(19) United States
(12) Patent Application Publication
(10) Pub. No.: US 2024/0418606 A1
(43) Pub. Date: Dec. 19, 2024

(54) DEVICE FOR CALIBRATING A SPALL PROPAGATION MODEL OF A BEARING AND ASSOCIATED METHOD AND SYSTEM

(71) Applicant: Aktiebolaget SKF, Göteborg (SE)

(72) Inventors: Cornelis Harm TAAL, Utrecht (NL); Stephan BAGGEROHR, Houten (NL); Hendrik Anne MOL, Varik (NL); Guillermo Enrique MORALES ESPEJEL, Ijsselstein (NL)

(21) Appl. No.: 18/735,377

(22) Filed: Jun. 6, 2024

(30) Foreign Application Priority Data
Jun. 14, 2023 (DE) 102023205542.2

(51) Int. Cl. G01M 13/045; G06F 30/20

(52) U.S. Cl. CPC G01M 13/045; G06F 30/20

(57) ABSTRACT

A device (1) for calibrating a spall propagation model (12a) of a bearing (3) includes a processing means (8) for determining a condition indicator from measurements of the bearing (3). A determining means (9) determines a first calibrating value (CV1) representative of the appearance of a spall in a stationary ring (4) or rotating ring (5) of the bearing (3) after N1 number of revolutions of the bearing and a second calibrating value (CV2) representative of the evolution of the spall in the stationary ring (4) or rotating ring (5) after N2 number of revolutions of the bearing from the condition indicator. N2 is greater than N1. Identifying means (10) identifies at least one stage of propagation of the spall from the two calibrating values (CV1, CV2). A calibrating means (11) calibrates the spall propagation model (12a) from the two calibrating values (CV1, CV2).

### CROSS-REFERENCE TO RELATED APPLICATION

This application claims priority to German Application No. 102023205542.2, filed Jun. 14, 2023, the entirety of which is hereby incorporated by reference.

### FIELD

The present disclosure is directed to models for determining spall propagation in bearings.

More particularly, the present disclosure deals with a method and a device for calibrating a spall propagation model, and a system comprising such a device and a spall propagation model.

### BACKGROUND

Generally, a bearing is replaced when a critical spall size is detected using spectrum analysis of vibration measurements so that preventive maintenance operations may not be planned to prevent a unexcepted stop of a machine comprising the said bearing.

An estimation of the remining useful life RUL of the bearing to prevent critical failures is currently made by experts for specific applications.

Consequently, maintenance operations may be planned to change the bearing when the remaining useful life is less than a predetermined value to optimize the duration of use of the said machine.

However, the estimation of the RUL of the bearing made by experts is not scalable and based on experience of the experts so that the estimation varies according to the expert.

The estimation is not reliable.

Further, spall propagation models are available to make prognosis.

To issue reliable prognosis, the spall propagation models need to be calibrated.

However, as there is no exact knowledge of the values of input parameters of the models comprising for example the relation with speed of the bearing, load applied on the bearing, material and heat treatment of the bearing, lubricant, temperature, and/or pressure, so that the spall propagation model may be calibrated accurately to output predicted spall sizes with enough accuracy in order to issue reliable prognosis.

Consequently, the present disclosure intends to calibrate a spall propagation model to predict the spall size accurately for example to estimate the remaining useful life of a bearing in a reliable way.

### SUMMARY

According to an aspect, a method for calibrating a spall propagation model of a bearing is proposed.

The bearing comprises a stationary ring and a rotating ring capable of rotating concentrically relative to the stationary ring, and rolling elements interposed between the stationary and rotating rings, the method comprises:
determining measurements of the bearing during predetermined durations to get at a plurality of recordings and measuring the number of revolutions of the bearing,
processing the measurements to determine a condition indicator,
determining a first calibrating value representative of the appearance of a spall in the stationary ring or rotating ring of the bearing after N1 number of revolutions of the bearing and a second calibrating value representative of the evolution of the spall in the stationary ring or rotating ring after N2 number of revolutions of the bearing from the condition indicator, N2 being greater than N1,
identifying at least one stage of propagation of the spall from the two calibrating values, and
calibrating the spall propagation model from the two calibrating values.

Only two calibrating values need to be determined to calibrate the spall propagation model on contrary to methods known from the prior art which need to know values of input parameters of the spall propagation model, in order to predict the spall size with enough accuracy to determine for example the RUL of the bearing for planning maintenance operations.

Preferably, processing the measurements and determining the first calibrating value comprise for each recording:
performing a spectral analysis of the measurements to determine the frequency spectrum of the measurements,
determining a condition indicator value, the condition indicator value being the sum of the amplitudes of the identified frequency bins having a frequency equal to a multiple integer of a predetermined frequency depending on the number of revolutions of the bearing and representative of the defect of the bearing,

when the condition indicator value is determined for each recording:
performing a trend analysis of the condition indicator values to identify a first positive gradient of the condition indicator values associated to the smallest number of revolutions,
identifying a first reference value associated to the condition indicator value of the first positive gradient and the number of revolutions associated to the first reference value,
the first calibrating value being equal to the number of revolutions associated to the first reference value.

Advantageously, determining the second calibrating value comprises for each recording identifying a local extremum of at least one frequency bin and the associated number of revolutions, the second calibrating value being equal to a predetermined spall size according to the parity of the frequency bin.

Preferably, when at least the first frequency bin has a local maximum amplitude associated with the smallest number of revolutions, the second calibrating value is equal to the number of revolutions associated to the said local maximum amplitude and being representative of the size of the spall equal to half the circumferential distance between two contact points of two neighbouring rolling elements on a raceway of the bearing.

Advantageously, processing the measurements and determining the first calibrating value comprise for each recording:
performing a repetitive Fourier transform RFT of the measurements to obtain an excitation-frequency spectrum associated with a predetermined frequency,
determining a condition indicator value, the condition indicator being the sum of the amplitudes of excited frequency bins having an excitation frequency equal to a multiple integer of the predetermined frequency depending on the number of revolutions of the bearing and representative of the defect of the bearing,

when the condition indicator value is determined for each recording:
performing a trend analysis of the condition indicator values to identify a first positive gradient of the condition indicator values associated to the smallest number of revolutions,
identifying a first reference value associated to the condition indicator value of the first positive gradient and the number of revolutions associated to the first reference value,
the first calibrating value being equal to the number of revolutions associated to the first reference value.

Preferably, determining the second calibrating value comprises for each recording:
performing a trend analysis of the condition indicator values to identify a gradient equal to zero associated to the smallest number of revolutions, the smallest number of revolutions associated to the gradient equal to zero being larger than the smallest number of revolutions associated to the first positive gradient of the condition indicator values,
identifying a second reference value associated to the gradient equal to zero and the number of revolutions associated to the second reference value, the second calibrating value being equal to the number of revolutions associated to the second reference condition indicator value and being representative of the size of the spall equal to the size of the Hertzian contact between a rolling element and the stationary ring or the rotating ring.

Advantageously, the predetermined frequency is equal to the Ball Pass Frequency Outer of the bearing, the Ball Pass Frequency Inner of the bearing, or the Ball Spin Frequency of the bearing.

Preferably, calibrating the spall propagation model comprises inputting the first and second calibrating values and varying at least one input parameter of the spall propagation model so that the predicted spall size outputted by the model is equal to the spall size associated to the calibrating values.

According to another aspect, a device for calibrating a spall propagation model of a bearing is proposed.

The bearing comprises a stationary ring and a rotating ring capable of rotating concentrically relative to the stationary ring, and rolling elements interposed between the stationary and rotating rings.

The device comprises:
processing means configured to determine a condition indicator from measurements of the bearing,
determining means configured to determine a first calibrating value representative of the appearance of a spall in the stationary ring or rotating ring after N1 number of revolutions of the bearing and a second calibrating value representative of the evolution of the spall in the stationary ring or rotating ring after N2 number of revolutions of the bearing from the condition indicator, N2 being greater than N1,
identifying means configured to identify at least one stage of propagation of the spall from the two calibrating values, and
calibrating means configured to calibrate the spall propagation model from the two calibrating values.

According to another aspect, a system comprising a device for calibrating a spall propagation model as defined above and spall propagation model of a bearing.

### BRIEF DESCRIPTION OF THE DRAWINGS

Other advantages and features of the present disclosure will appear on examination of the detailed description of embodiments, in no way restrictive, and the appended drawings in which:

FIG. 1 illustrates schematically an example of a device for calibrating a spall propagation model of a bearing according to the present disclosure;

FIG. 2 illustrates schematically a first example of a method for calibrating the spall propagation model according to the present disclosure;

FIG. 3 illustrates schematically an example of frequency bins determined during the spectral analysis according to the present disclosure,

FIG. 4 illustrates schematically a second example of a method for calibrating the spall propagation model according to the present disclosure, and

FIG. 5 illustrates schematically an example of condition indicator values according to the number of revolutions of the bearing according to the present disclosure.

### DETAILED DESCRIPTION

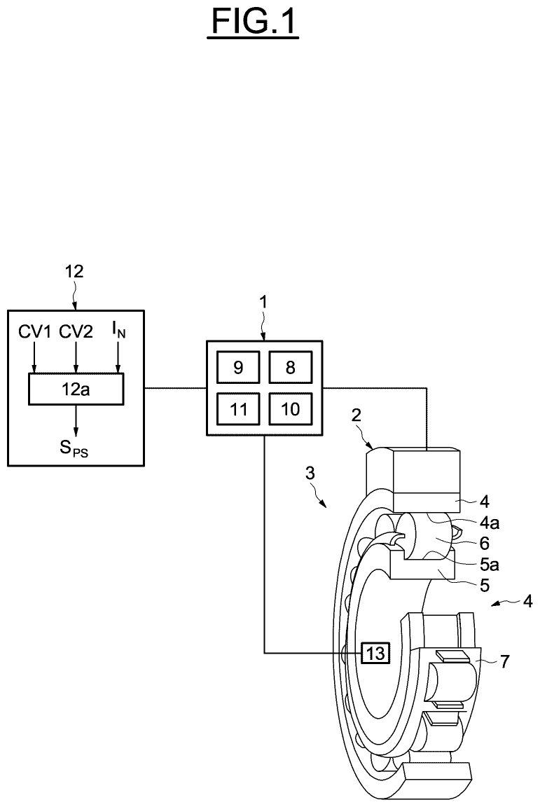

Reference is made to FIG. 1 which represents schematically an example of a device 1 for calibrating a spall propagation model of a bearing.

The device 1 is connected to a first sensor 2 intended to determine measurements of a bearing 3.

The first sensor 2 may measure acceleration, gyroscopic velocity, absolute or relative displacement, strain, or vibration.

In the following, it is assumed that the first sensor 2 determine vibrations of the sensor 3.

The bearing 3 includes a stationary ring 4 and a rotating ring 5 capable of rotating concentrically relative to one another.

It is assumed that the stationary ring 4 is the outer ring of the bearing 3 and the rotating ring 5 is the inner ring of the bearing 3, the inner ring being tightening to a shaft (not represented).

The stationary ring 4 comprises a raceway 4a and the rotating ring 5 comprises a raceway 5a.

The bearing 3 further comprises rolling elements 6 interposed between the stationary and rotating rings 4, 5, and rolling on the raceways 4a, 5a of the stationary and rotating rings 4, 5.

At least one cage 7 maintains the circumferential spacing of the rolling elements 6.

As represented on FIG. 1, the rolling elements 6 are rollers.

In variant, the rolling elements 6 may be balls.

The bearing 3 includes one raw of rolling elements 6. In variant, the bearing 3 may include more than one raw of rolling elements 6.

The device 1 comprises processing means 8, determining means 9, identifying means 10, and calibrating means 11.

The device 1 is further connected to a circuit 12 implementing a spall propagation model 12a, and to a second sensor 13 intended to measure the rotation speed of the rotating ring 5.

The spall propagation model 12a receives as inputs a first calibrating value CV1, a second calibrating value CV2, and an input vector I_{N} comprising at least one input parameter.

The spall propagation model 12a outputs a predicted spall size Sps.

The vector I_{N} may comprise more than one input parameters.

Input parameters are for example loads applied on the bearing 3, temperature of the bearing 3, pressure applied on the rolling elements 6, material properties of the bearing 3, type of lubricant used to lubricate the bearing 3, lubrification conditions of the bearing 3.

The device 1 connected to the circuit 12 form a system intended for example to issue prognosis about the useful remaining life URL of the bearing 3.

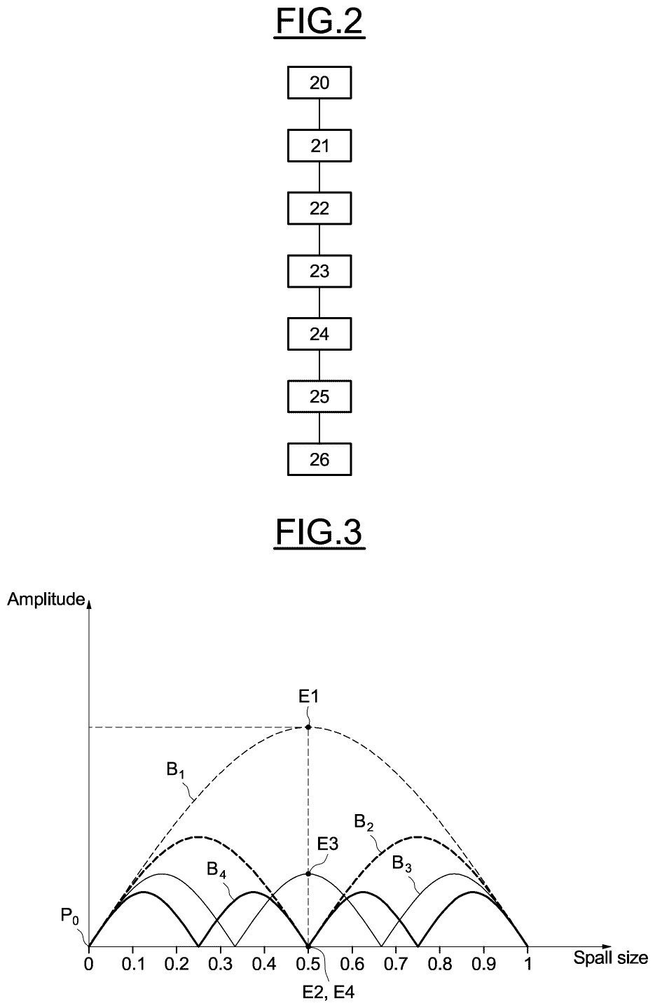

FIG. 2 illustrates schematically a first example of a method for calibrating the spall propagation model 12 implementing the device 1.

In a step 20, the first sensor 2 delivers vibration measurements of the bearing 3.

In a step 21, the processing means 8 process the measurements of the sensor 2 to determine a plurality of recordings and associate the number of revolutions of the rotating ring 5 determined from rotation speed measurements delivered by the second sensor 13.

In a step 22, the processing means 8 process the vibration measurements to determine a condition indicator and the determining means 9 determine the first calibrating value CV1 representative of the appearance of a spall in the stationary ring 5 or rotating ring 4 and the second calibrating value CV2 representative of the evolution of the spall in the stationary ring 5 or rotating ring 4 from the condition indicator.

The processing means 8 perform for each recording a spectral analysis of the measurements to determine the frequency spectrum of the measurements. The processing means 8 implement for example a Fast Fourier Transform FFT algorithm to perform the spectral analysis.

The determining means 9 determine a condition indicator value for each recording.

The condition indicator value is equal to the sum of the amplitude of identified frequency bins having a frequency equal to a multiple integer of a predetermined frequency depending on the number of revolutions of the bearing 3.

The predetermined frequency is representative of the defect of the bearing 3.

The predetermined frequency is equal to the Ball Pass Frequency Outer BPFO of the bearing 3, the Ball Pass Frequency Inner BPFI of the bearing 3, or the Ball Spin Frequency BSF of the bearing 3.

The Ball Pass Frequency Inner BPFI is equal to:

$$BPFI = N \cdot \frac{{N}_{B}}{2} ( 1 + \frac{{B}_{D}}{{P}_{D}} cos β ) \qquad ( 1 )$$

the Ball Pass Frequency Inner BPFI is equal to

$$BPFI = N \cdot \frac{{N}_{B}}{2} ( 1 - \frac{{B}_{D}}{{P}_{D}} cos β ) \qquad ( 2 )$$

the Ball Spin Frequency BSF is equal to

$$BPFI = N \cdot \frac{{P}_{D}}{{B}_{D}} ( 1 - {( \frac{{B}_{D}}{{P}_{D}} cos β )}^{2} ) \qquad ( 3 )$$

where N is the rotation speed of the rotating ring 4, N_{B} is the number of rolling elements, β is the angle of contact of the rolling elements, B_{D} is the diameter of the rolling elements, and P_{D} is the mean value of the raceways 4a, 5a.

FIG. 3 illustrates an example of frequency bins determined during the spectral analysis in step 22 of the recordings according to the normalized spall size.

The spall size equal to 1 means that the spall size is equal to the circumferential distance between two contact points of two neighbouring rolling elements 6 on one raceway of the raceway 4a of the stationary ring 4 and the raceway 5a of the rotating ring 5a of the bearing 3.

B₁, B₂, B₃, B₄ designate respectively the first harmonic, the second harmonic, the third harmonic and the fourth harmonic.

Of course, more frequency bins may be taken into account.

During a step 23, when for each recording the condition indicator value is determined, the processing means 8 perform a trend analysis of the condition indicator values to identify a first positive gradient of the condition indicator values associated to the smallest number of revolutions.

The point P0 (FIG. 3) is associated to the first positive gradient of the condition indicator values having the smallest number of revolutions.

The process means 8 identify a first reference value associated to the condition indicator value (point P0) of the first positive gradient and the number of revolutions associated to the first reference value (point P0).

The first calibrating value CV1 is equal to the number of revolutions N1 associated to the first reference value.

During a step 24, the processing means 8 determine the second calibrating value CV2.

For each recording, the processing means identify a local extremum of at least one frequency bin and the associated number of revolutions (FIG. 3).

The second calibrating value CV2 is equal to a predetermined spall size according to the parity of the frequency bin.

When the first frequency bin B₁ has a local maximum amplitude E1 associated with the smallest number of revolutions, the second calibrating value CV2 is equal to the number of revolutions N2 associated to the said local maximum amplitude E1 and is representative of the size of the spall equal to half the circumferential distance between two contact points of two neighbouring rolling elements 6 on one raceway of the raceway 4a of the stationary ring 4 and the raceway 5a of the rotating ring 5a of the bearing 3.

In variant, when the first frequency bin B₁ and the third frequency bin B₃ have a local maximum amplitude E1, E3 associated with the smallest number of revolutions N2, the second calibrating value CV2 is equal to the number of revolutions associated to the said local maximum amplitudes E1, E3 and is representative of the size of the spall equal to half the circumferential distance between two contact points of two neighbouring rolling elements 6 on one raceway of the raceway 4a of the stationary ring 4 and the raceway 5a of the rotating ring 5a of the bearing 3.

In another variant, when the odd frequency bins B₁, B₃ have a local maximum amplitude E1, E3 and the even frequency bins B₂, B₄ have a local minimum amplitude E1, E3 associated with the smallest number of revolutions N2, the second calibrating value CV2 is equal to the number of revolutions associated to the said local maximum and minimum amplitudes E1, E3, E2, E4 and is representative of the size of the spall equal to half the circumferential distance between two contact points of two neighbouring rolling elements 6 on one raceway of the raceway 4a of the stationary ring 4 and the raceway Sa of the rotating ring 5a of the bearing 3.

Other extremums of frequency bins may be identified to determine values of the spall size, for example when the spall size is equal to a quarter of the circumferential distance between two contact points of two neighbouring rolling elements 6 on one of the raceway 4a of the stationary ring 4 and the raceway 5a of the rotating ring 5a of the bearing 3.

The number of revolutions N2 is greater than the number of revolutions N1.

In a step 25 (FIG. 2), the identifying means 10 identify the stage of propagation of the spall from the two calibrating values CV1, CV2.

In this case, the identifying means 10 identify the propagation of the spall between the appearance of the spall on one of both raceways 4a, 5a associated to the first calibrating value CV1 and until the spall has reached a length of half of the circumferential distance between two contact points of two neighbouring rolling elements 6 associated to the second calibrating value CV2.

During a step 26, the calibrating means 11 calibrate the spall propagation model 12 from the two calibrating values CV1, CV2.

The calibrating means 11 input the two calibrating values CV1, CV2 in the spall propagation model 12a and vary the input parameter(s) of the input vector I_{N} so that the predicted spall size Sps outputted by the model 12a is equal to the spall size associated to the calibrating values CV1, CV2.

The model 12a may be a linear model having one input parameter.

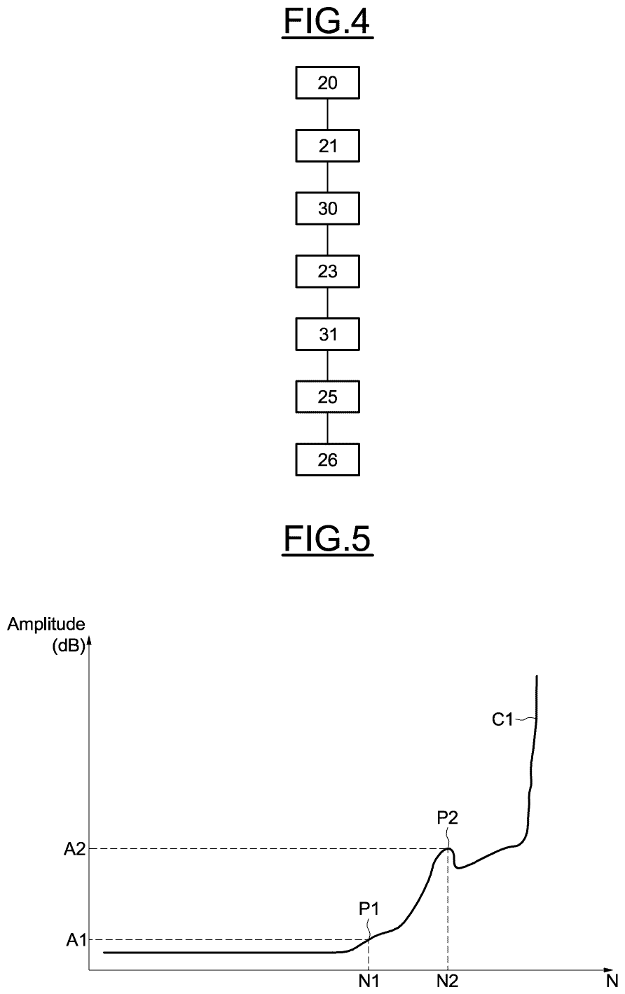

FIG. 4 illustrates schematically a second example of a method for calibrating the spall propagation model 1 implementing the device 1.

Steps 20, 21 are performed.

During a step 30, the processing means 8 process the vibration measurements to determine a condition indicator, and the determining means 9 determine the first calibrating value CV1 representative of the appearance of a spall in the stationary ring 5 or rotating ring 4 and the second calibrating value CV2 representative of the evolution of the spall in the stationary ring 5 or rotating ring 4 from the condition indicator.

The processing means 8 perform for each recording a repetitive Fourier transform RFT of the measurements to obtain an excitation-frequency spectrum.

The document U.S. Pat. No. 5,698,788 describes an example of processing the RFT.

The determining means 9 determine a condition indicator value for each recording.

The condition indicator value is equal to the sum of the amplitude of identified excited frequency bins having an excitation frequency equal to a multiple integer of a predetermined frequency depending on the number of revolutions of the bearing 3 and representative of the defect of the bearing 3.

FIG. 5 illustrates an example of condition indicator values (curve C1) of a recording according to the number of revolutions of the rotating ring 4, the predetermined frequency being the Ball Pass Frequency Outer BPFO of the bearing 3.

When the condition indicator value is determined for each recording, step 23 is performed.

The point P1 (FIG. 5) is associated to the first positive gradient of the condition indicator values having the first smallest number of revolutions N1.

During a step 31, the processing means 8 perform for each recording a trend analysis of the condition indicator values to identify a gradient equal to zero associated to the smallest number of revolutions, the smallest number of revolutions associated to the gradient equal to zero being larger than the first smallest number of revolutions associated to the first positive gradient of the condition indicator values, and identify a second reference value associated to the gradient equal to zero and the number of revolutions associated to the second reference value.

The point P2 (FIG. 5) is associated to the gradient equal to zero of the condition indicator values having the second smallest number of revolutions N2.

The number of revolutions N2 is greater than the number of revolutions N1.

The second calibrating value CV2 is equal to the number of revolutions associated to the second reference condition indicator value and is representative of the size of the spall equal to the size of the Hertzian contact in the axial direction of the bearing 3 between a rolling element 6 and one of the stationary ring 4 and the rotating ring 5.

Steps 25 and 26 are performed.

The method for calibrating the spall propagation model 12a is based on determining input parameters of the model 12a so that the predicted spall sized outputted by the model 12a on at least the two calibrating values is equal to the spall size associated to the calibrating values.

The values of the input parameters need no to be determined on contrary to calibrating methods known form the prior art.

The calibrated spall propagation model 12a may be used to determine the remaining useful life RUL of the bearing 3 with a growing damage on the surface of the raceway of the stationary ring 4 or rotating ring 5 which is crucial to optimize and extend maintenance intervals of the bearing 3 to prevent costs and hazards.

What is claimed is:

1. A method for calibrating a spall propagation model of a bearing, the bearing comprising a stationary ring and a rotating ring capable of rotating concentrically relative to the stationary ring, and rolling elements interposed between the stationary and rotating rings, the method comprises:
determining measurements of the bearing during predetermined durations to get at a plurality of recordings and measuring the number of revolutions of the bearing,
processing the measurements to determine a condition indicator,
determining a first calibrating value representative of the appearance of a spall in the stationary ring or rotating ring after N1 number of revolutions of the bearing and a second calibrating value representative of the evolution of the spall in the stationary ring or rotating ring after N2 number of revolutions of the bearing from the condition indicator, N2 being greater than N1,
identifying at least one stage of propagation of the spall from the two calibrating values, and
calibrating the spall propagation model from the two calibrating values.

2. The method according to claim 1, wherein processing the measurements and determining the first calibrating value comprise for each recording:
performing a spectral analysis of the measurements to determine the frequency spectrum of the measurements,
determining a condition indicator value, the condition indicator value being the sum of the amplitudes of the identified frequency bins having a frequency equal to a multiple integer of a predetermined frequency depending on the number of revolutions of the bearing and representative of the defect of the bearing,
when the condition indicator value is determined for each recording:
performing a trend analysis of the condition indicator values to identify a first positive gradient of the condition indicator values associated to the smallest number of revolutions,
identifying a first reference value associated to the condition indicator value of the first positive gradient and the number of revolutions associated to the first reference value,
the first calibrating value being equal to the number of revolutions associated to the first reference value.

3. The method according to claim 2, wherein determining the second calibrating value comprises for each recording identifying a local extremum of at least one frequency bin and the associated number of revolutions, the second calibrating value being equal to a predetermined spall size according to the parity of the frequency bin.

4. The method according to claim 3, wherein when at least the first frequency bin has a local maximum amplitude associated with the smallest number of revolutions, the second calibrating value is equal to the number of revolutions associated to the said local maximum amplitude and being representative of the size of the spall equal to half the circumferential distance between two contact points of two neighbouring rolling elements on a raceway of the bearing.

5. The method according to claim 1, wherein processing the measurements and determining the first calibrating value comprise for each recording:
performing a repetitive Fourier transform of the measurements to obtain an excitation-frequency spectrum,
determining a condition indicator value, the condition indicator being the sum of the amplitudes of excited frequency bins having an excitation frequency equal to a multiple integer of the predetermined frequency depending on the number of revolutions of the bearing and representative of the defect of the bearing,
when the condition indicator value is determined for each recording:
performing a trend analysis of the condition indicator values to identify a first positive gradient of the condition indicator values associated to the smallest number of revolutions,
identifying a first reference value associated to the condition indicator value of the first positive gradient and the number of revolutions associated to the first reference value,
the first calibrating value being equal to the number of revolutions associated to the first reference value.

6. The method according to claim 5, wherein determining the second calibrating value comprises for each recording:
performing a trend analysis of the condition indicator values to identify a gradient equal to zero associated to the smallest number of revolutions, the smallest number of revolutions associated to the gradient equal to zero being larger than the smallest number of revolutions associated to the first positive gradient of the condition indicator values,
identifying a second reference value associated to the gradient equal to zero and the number of revolutions associated to the second reference value,
the second calibrating value being equal to the number of revolutions associated to the second reference condition indicator value and being representative of the size of the spall equal to the size of the Hertzian contact between a rolling element and the stationary ring or the rotating ring.

7. The method according to claim 1, wherein the predetermined frequency is equal to the Ball Pass Frequency Outer of the bearing, the Ball Pass Frequency Inner of the bearing, or the Ball Spin Frequency of the bearing.

8. The method according to claim 1, wherein calibrating the spall propagation model comprises inputting the first and second calibrating values and varying at least one input parameter of the spall propagation model so that the predicted spall size outputted by the model is equal to the spall size associated to the calibrating values.

9. The method according to claim 4, wherein the predetermined frequency is equal to the Ball Pass Frequency Outer of the bearing, the Ball Pass Frequency Inner of the bearing, or the Ball Spin Frequency of the bearing.

10. The method according to claim 4, wherein calibrating the spall propagation model comprises inputting the first and second calibrating values and varying at least one input parameter of the spall propagation model so that the predicted spall size outputted by the model is equal to the spall size associated to the calibrating values.

11. A device for calibrating a spall propagation model of a bearing, the bearing comprising a stationary ring and a rotating ring capable of rotating concentrically relative to the stationary ring, and rolling elements interposed between the stationary and rotating rings, the device comprising:
processing means configured to determine a condition indicator from measurements of the bearing,
determining means configured to determine a first calibrating value representative of the appearance of a spall in the stationary ring or rotating ring of the bearing after N1 number of revolutions of the bearing and a second calibrating value representative of the evolution of the spall in the stationary ring or rotating ring after N2 number of revolutions of the bearing from the condition indicator, N2 being greater than N1,
identifying means configured to identify at least one stage of propagation of the spall from the two calibrating values, and
calibrating means configured to calibrate the spall propagation model from the two calibrating values.

12. A system comprising the device according to claim 11 and a spall propagation model of a bearing.
